(19) United States
(12) Patent Application Publication
(10) Pub. No.: US 2006/0096705 A1
(43) Pub. Date: May 11, 2006

(54) Removal of sacrificial materials in MEMS fabrications

(76) Inventors: Hongqin Shi, San Jose, CA (US); Dmitri Simonian, Sunnyvale, CA (US)

Correspondence Address: REFLECTIVITY, INC., 350 POTRERO AVENUE, SUNNYVALE, CA, 94085, US

(21) Appl. No.: 11/303,063

(22) Filed: Dec. 14, 2005

Related U.S. Application Data
(63) Continuation-in-part of application No. 10/922,565, filed on Aug. 19, 2004.
Application No. 10/922,565 is a division of application No. 10/154,150, filed on May 22, 2002, now Pat. No. 6,800,210.

(51) Int. Cl. C03C 25/68; H01L 21/306

(52) U.S. Cl. 156/345.33; 216/58

(57) ABSTRACT

A method and apparatus for removing the sacrificial layers of microstructures in fabrications have been disclosed. The method comprises a plasma etching process followed by a non-energized spontaneous vapor phase etching process. The plasma and spontaneous etching processes utilize the same etchant that is capable of chemically reacting with the sacrificial material, wherein t chemical reaction is spontaneous.

### CROSS-REFERENCE TO RELATED PATENT APPLICATIONS

The present invention is a continuation-in-part of U.S. patent application Ser. No. 10/922,565 filed Aug. 19, 2004, which is a divisional of U.S. patent application Ser. No. 10/154,150 filed May 22, 2002, the subject matter of each being incorporated herein by reference in entirety.

The subject matter of each of following patents and patent applications is incorporated by reference in the instant US patent application.

| | | Attorney docket |
|---|---|---|
| Serial/U.S. Pat. No. | Filling Date | number |
| 10/269,149 | 10/12/2002 | P56-US |
| 10/305,507 | 11/26/2002 | P86-US |
| 10/665,998 | 09/17/2003 | P117-US |
| 10/666,671 | 09/17/2003 | P118-US |
| 10/805,610 | 03/18/2004 | P119-US |
| 10/666,002 | 09/17/2003 | P120-US |
| 10/713,671 | 11/13/2003 | P121-US |

### TECHNICAL FIELD OF THE INVENTION

The present invention is related generally to the art of fabrications of microstructures which includes, but not limited to, such devices as microelectromechanical systems, semiconductor devices; and, more particularly, to methods and apparatus for releasing processes in fabrications of the microstructures.

### BACKGROUND OF THE INVENTION

Sacrificial layers of selected sacrificial materials are commonly used in fabrications of microstructures, such as microelectromechanical systems and semiconductor devices. A typical sacrificial material is amorphous silicon. Once the desired structures of the microstructure are formed, the sacrificial layers are removed by etching—the process of which is often referred to as “release.”

More recently, etching methods using selected gas phase etchants have drawn great interests in microstructure industry due to many advantages, such as high selectivity, less contamination, and less process stiction as opposed to other applicable etching methods, such as wet etching techniques. Gas phase etching processes, however, may not always be efficient if used alone due to the gaseous natural of the etchant. In particular, sacrificial materials in fabrication often build oxide layers at their surfaces. These oxidation layers may exhibit strong resistance to gaseous etchant in gas phase etching processes as compared to wet etchant; and thus difficult to be removed precisely and efficiently.

Therefore, what is desired is a method and apparatus for removing sacrificial materials of microstructures in fabrications.

### SUMMARY OF THE INVENTION

In view of the foregoing, the present invention discloses a method and apparatus for removing sacrificial layers of microstructures in fabrications. The method comprises a plasma etching process followed by a non-energized vapor phase etching process. The plasma and non-energized etching processes both may utilize the same gaseous reactive etchant that is capable of chemically and spontaneously reacting with the sacrificial material.

Because both of the plasma and spontaneous etching processes may utilize the same gaseous etchant, a single etch chamber for carrying out both etching processes can be provided. Of course, multiple etch chambers can also be used. The single etch chamber may comprise multiple spaces for different purposes. Different gases introduced into the etch chamber, however, experience the same physical setup. In one example of the invention, the etch chamber comprises a plasma space and process space. The plasma space installed therein a plasma generator for energizing the gaseous etchant, and generating atomic radicals from the gaseous etchant. The energized atomic radicals are streamed to the process space wherein the target microstructure sample with sacrificial material surfaces is disposed for removing the sacrificial materials, especially the oxide layers on the sacrificial materials.

At a time when at least a portion of the sacrificial materials previously covered and protected by the oxide layers are exposed, the plasma generator can be stopped; and the plasma etching process can be terminated. The spontaneous gaseous etchant is then introduced to the process space and streamed to the exposed sacrificial materials without being energized by the plasma generator. Specifically, the spontaneous vapor phase etchant can be streamed to the process space without being energized into radicals. The gaseous etchant chemically reacts with the molecules of the sacrificial material, which results in etching products. The etching products are desorbed and removed from the sacrificial layers. This non-energized gaseous etching process can be performed until all target sacrificial materials are substantially removed.

In either one of the two etching processes, the selected gaseous etchant can be introduced into the processing chamber of the etch chamber continuously or intermittently or a combination thereof through a feeding route that may or may not form a circulation loop that passes through the etch chamber. In one example of the invention, the gaseous etchant can be continuously introduced into the etch chamber during the plasma etching process. In the spontaneous etching process, the gaseous etchant can be streamed into the etch chamber through the first circulation loop passing through the etch chamber with the first circulation loop comprising the loop through which the plasma etchant is introduced into the etch chamber. When a predetermined amount of gaseous etchant is introduced into the etch chamber, the etchant source is closed. The etchant fed into the etch chamber is then circulated via the etch chamber through the second circulation loop passing through the etch chamber. The feeding and circulating the etchant in the second circulation loop alternate until substantially all the target sacrificial materials are removed from the microstructure.

Because the two etching processes utilize the same etchant for multiple steps in the etching process, the etching system can be connected to the same etchant for plasma and non-plasma etching if desired. For facilitating the etching processes, other non-etching gases, such as diluent gases, can be connected to the etching system and mixed with the selected gaseous etchant. The diluent gas can be inert gases, such as helium, nitrogen, argon, and xenon.

The objects and advantages of the present invention will be obvious, and in part appear hereafter and are accomplished by the present invention. Such objects of the invention are achieved in the features of the independent claims attached hereto. Preferred embodiments are characterized in the dependent claims.

### BRIEF DESCRIPTION OF THE DRAWINGS

The accompanying drawings are illustrative but not to scale. In addition, some elements are omitted from the drawings to more clearly illustrate the embodiments. While the appended claims set forth the features of the present invention with particularity, the invention, together with its objects and advantages, may be best understood from the following detailed description taken in conjunction with the accompanying drawings, in which:

FIG. 1 schematically illustrates an etch chamber in which a plasma and non-energized etching processes can be performed according to the invention;

FIG. 2 demonstratively illustrates a plasma generator useable in the etch chamber in FIG. 1;

FIG. 3 demonstratively illustrates another plasma generator useable in the etch chamber in FIG. 1;

FIG. 4 schematically illustrates an exemplary etch system incorporating the etch chamber in FIG. 1 according to an example of the invention;

FIG. 5 is a flow chart showing the steps executed for removing the sacrificial materials of a microstructure with the etching system in FIG. 4 in an exemplary etching process;

FIG. 6 is a cross-sectional view of an exemplary micromirror that can be released with the embodiments of the invention;

FIG. 7 is a cross-sectional view of the micromirror in FIG. 6 during a fabrication before releasing;

FIG. 8a and FIG. 8b illustrate an exemplary method for fabricating a micromirror array with the methods of the invention;

FIG. 9a and FIG. 9b illustrate an exemplary wafer-lever fabrication for a plurality of micromirror arrays according to an embodiment of the invention; and

FIG. 10 demonstratively illustrates a perspective view of a singulated micromirror device formed from the assembly of the wafers shown in FIGS. 9a and 9b.

### DETAILED DESCRIPTION OF THE DRAWINGS

The present invention discloses a method for removing sacrificial materials of microstructures in fabrications with a plasma etching process followed by a non-energized gaseous etching process. The same gaseous etchant capable of spontaneously and chemically reacts with the target sacrificial materials can be used in both plasma and non-energize processes. Specifically, the gaseous etchant is energized into radicals in the plasma process particularly for removing the oxide layers on the surfaces of the sacrificial materials. After at least a portion of the sacrificial materials is uncovered, the same etchant is used for removing the sacrificial materials but without being energized into radicals. In the following, the present invention will be discussed with reference to drawings of specific examples. However, it will be understood that the following discussion is for demonstration purposes, and should not be interpreted as a limitation. Instead, any variations without departing from the spirit of the invention are applicable.

In fabrications of microstructures, selected sacrificial materials, such as amorphous silicon or other suitable materials, are deposited and patterned so as to form desired structural elements of the microstructures. Surfaces of the sacrificial materials exposed to the fabrication environment are often oxidized into oxide layers. The oxide materials in the oxide layers can exhibit strong resistance to non-energized gas phase etch processes, such as the processes with spontaneous vapor phase etchants. For efficiently removing the sacrificial materials with high selectivity, an energized etch process for removing at least a portion, though preferably all, of the oxide layers on the sacrificial materials is performed. For obtaining a high selectivity, efficiency, precise controllability, less contamination and less process stiction as opposed to other posible etching methods, such as wet etching, a non-energized etch process with the spontaneous etchant is performed following the plasma etch process.

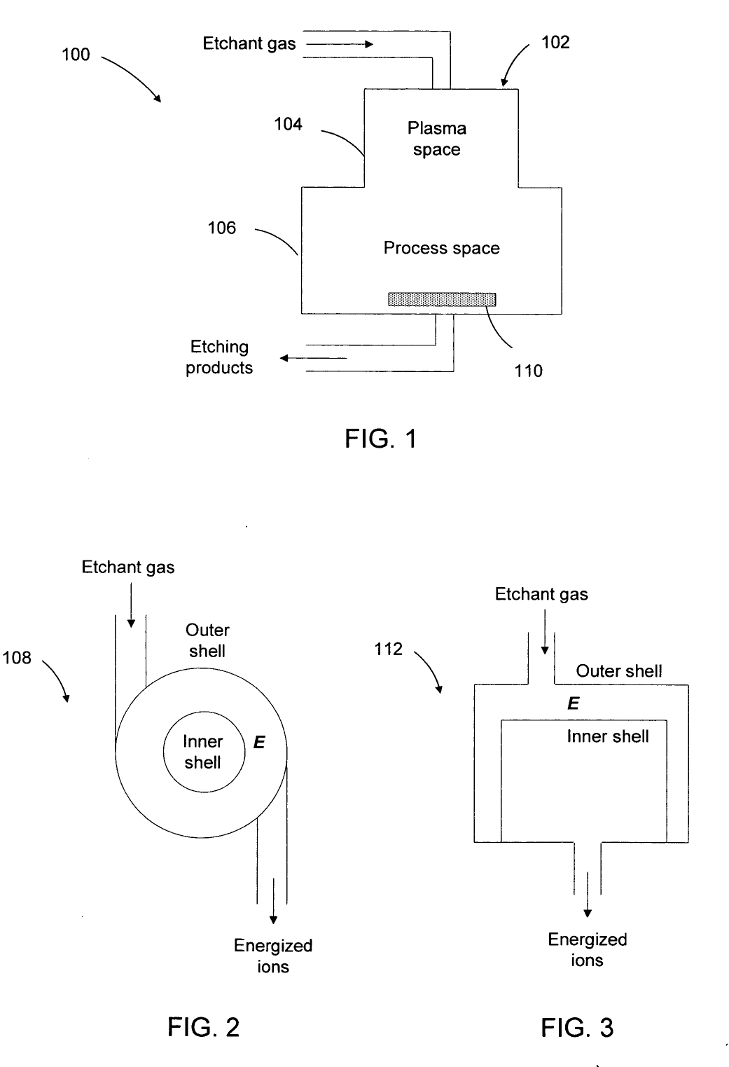

Because the plasma etch and non-energized etch processes utilize etchants that comprise the same spontaneous gases etchant, the two separate etching processes can be performed if desired in the same etch chamber (though not required), as shown in FIG. 1.

Referring to FIG. 1, a portion of etching system 100 is illustrated therein. The etching system comprises etch chamber 102. The etch chamber comprises plasma space 104 and process space 106. Microstructure sample 110 having sacrificial materials to be removed is disposed within the process space, for example, held in the process space by a sample holder (not shown). The sample holder can be a pillar with a stage on top with sample holding mechanisms for holding the sample, and may incorporate other features, such as moving mechanisms (e.g. motor) for dynamically adjusting the position within the etch chamber.

The plasma space has a plasma generator installed therein for generating plasma radicals. Specifically, at least one or both of the anode and cathode of the plasma generator are located within the plasma generating space. The plasma generator can be any suitable plasma generator, such as Radio-Frequency generators (e.g. capacitive coupled RF plasma generators, inductive coupled RF plasma generators). Exemplary plasma generators are schematically illustrated in FIGS. 2 and 3.

Referring to FIG. 2, plasma generator 108 comprises an inner metallic shell and outer metallic shell disposed to form a circular tunnel therebetween. The inner and outer metallic shells are operated as anode and cathode. In operation an electrical field E is established between the inner and outer metallic shells; and the etchant gas flows into the plasma generator through the tunnel between the inner and outer metallic shells. The gaseous etchant, as passing through the tunnel, are dissociated into reactive and energized molecules—which are often referred to as reactive atomic radicals. The dissociated and energized radicals are exit from the tunnel of the plasma generator; and streamed to the target sacrificial layers in the process space for removing the sacrificial materials, especially the oxide layers on the surfaces of the sacrificial materials.

Another exemplary plasma generator usable in the etch chamber in FIG. 1 is demonstratively illustrated in FIG. 3. Referring to FIG. 3, plasma generator 112 comprises inner and outer metallic shells, between which an electrical field can be established. The electrical field has a magnitude high enough to dissociate the molecules of the selected gaseous etchant into energized atomic radicals. The dissociated atomic radicals can then be released from an exit connected to the space between the inner and outer shells. Alternatively, the dissociated atomic radicals can be released from one or more apertures made in the inner shell, which is not shown in the figure.

The dissociated atomic radicals from the plasma space are streamed to the microstructure in the process space for removing the sacrificial materials, especially the oxide layers on the sacrificial materials of the microstructure.

As a way of example without losing the generality, the sacrificial material of the microstructure in the etch chamber can be amorphous silicon; and gaseous xenon difluoride can be used as the etchant. For amorphous silicon, other etchants can also be used, such as gaseous interhalogens, other noble gas halides, fluorinated carbons and other chemical materials. The sacrificial material can be any other suitable materials such as polysilicon. Depending upon the sacrificial material and structural materials selected for the microstructures, etchants may vary. If necessary, different gaseous etchants can be used for removing the sacrificial material in the microstructure.

Referring again to FIG. 1, it is assumed that microstructure 110 has a sacrificial material of amorphous silicon; and the exposed surfaces of the amorphous silicon material comprise silicon dioxide (SiO₂). The silicon dioxide surface layers exhibit strong resist to spontaneous XeF₂ gas and isolate the underneath amorphous silicon from reaction with the spontaneous XeF₂ gas. Therefore, the surface SiO₂ layers need to be removed prior to etching the amorphous silicon sacrificial material. In one example of the invention, the surface SiO₂ layer can be removed using a plasma XeF₂ etch process; while the sacrificial amorphous silicon can be removed using a non-energized etch process with gaseous XeF₂. As a way of example, XeF₂ gas flows through the plasma generator in the plasma space where XeF₂ molecules are dissociated into atomic radicals of Xe and F. This dissociation process can be expressed as:
XeF₂→Xe+2F

The dissociated atomic radicals are streamed down to the process space and are adsorbed to SiO₂ molecules. Fluorine molecules F react chemically with SiO₂ molecules and generate chemical products including SiF₄ and oxygen gas. The chemical reaction can be expressed as:
SiO₂+4F→SiF₄+O₂

SiF₄, as well as oxygen gas, is a volatile material at room temperature, and departs from the SiO₂ surface (or the amorphous silicon surface), resulting in exposure of the underneath amorphous silicon material. The chemical products, such as SiF4 and oxygen, from the plasma etching process are pumped out from etch chamber 102 as shown in the figure.

During the plasma etch process, XeF₂ gas can be introduced to the plasma generator (and the etch chamber) continuously throughout the entire plasma etch process. Alternatively, XeF₂ can be intermittently introduced to the plasma generator (and the etch chamber) over time. In either case, XeF₂ gas can be introduced with or without a circulation loop that passes through the plasma generator and etch chamber.

The above discussed plasma etching process can be performed at room temperature or any suitable temperatures preferably above the room temperature such that the by-products from the plasma etch process are in gas phase. The pressure inside the etch chamber (e.g. the pressure of the process space) can be at one atmosphere or lower, or other suitable pressures, such as. from zero to 600 Torr.

When at least a portion of the SiO₂ surface layer is removed, though preferable all SiO₂ surface layers are removed, the plasma generator is shut down. When the plasma generator is shut down, the electrical field E between the anode and cathode is removed; while the tunnel of the plasma generator is still opened allowing for the etchant gas to pass through.

Without the electrical field between the iner and outer shells, XeF₂ gas passing through the tunnel and exit from the plasma generator is not ionized or energized. Such non-energized XeF₂ gas arrives at the amorphous silicon material of the microstructure in the process space, and spontaneously and chemically reacts with the amorphous silicon. The chemical reaction can be expressed as:
Si+2XeF₂→SiF₄+2Xe

Volatile SiF₄ molecules, as well as xenon gas, from the chemical reaction depart from the sacrificial layer, and can be pumped out from the etch chamber. When substantially all amorphous silicon materials are removed, the non-energized etch process is terminated.

During the non-energized etch process with non-energized spontaneous etchant (xenon difluoride), the temperature of the process space in the etch chamber (may also be the etch chamber) can be maintained at room temperature; while the pressure in the process space can be substantially at one atmosphere or less, such as 600 Torr or less. Of course, the temperature and pressure of the process space during the non-energized etching process can be at other suitable values. For example, the pressure can be from 10 to 100 Torr, or preferably around 50 Torr. Alternatively, the pressure can be higher than one atmosphere.

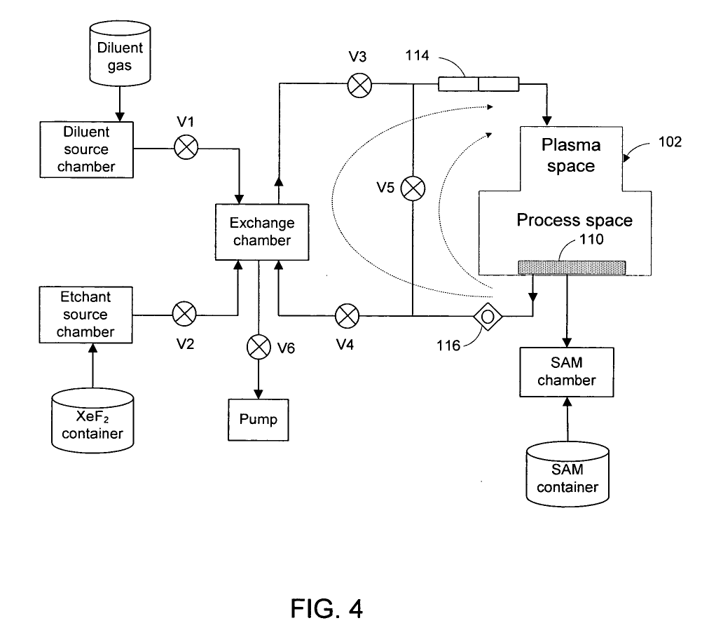

During the non-energized spontaneous etching process, XeF₂ gas can be streamed to the etch chamber with or without a circulation loop that passes through the etch chamber. An exemplary method for feeding XeF₂ will be discussed with reference to FIG. 4 in the following.

Referring to FIG. 4, an exemplary etch system with the etch chamber in FIG. 1 implemented therein is demonstratively illustrated. The etch system comprises etch chamber 102 as discussed with reference to FIG. 1. Microstructure sample 110 to be released is disposed in the process space of the etch chamber. The XeF₂ container containing XeF₂ (e.g. in solid state) is connected to the etchant source chamber wherein XeF₂ gas is prepared. The etchant source chamber is connected to the exchange chamber through valve V₂. The exchange chamber is provided for mixing XeF₂ gas with a diluent gas when necessary (e.g. in the non-energized etching process). The diluent gas can be an inert gas, such as helium, nitrogen gases, argon, krypton and xenon, or a combination thereof. The diluent gas is stored in the diluent gas container connected to the diluent source chamber that is connected to the exchange chamber via valve V₁.

The exchange chamber is connected to the etch chamber through valve V₃, circulation pump 114, and valve V₄. Etching detector 116 can be alternatively connected. The exchange chamber, valve V₃, circulation pump 114, etch chamber 102, and valve V₄ form a circulation loop (referred to as outer circulation loop in the following discussion). Valve V₅ is provided and disposed such that, valve V₅, circulation pump 114, and etch chamber 102 forming another circulation loop (referred to as inner circulation loop in the following discussion).

The cubic volume of the exchange chamber is preferably much less than (e.g. around one twentieth of, or one fiftieth of) the cubic volume of the etch chamber such that the volumetric amount of the mixed gas of XeF₂ and the diluent gas is much smaller than the mixed gas (including XeF₂, diluent gas and the etching products) in the etch chamber. As a result, the feeding of the mixed gas into the etch chamber during one feeding cycle is a small perturbation to and does not dramatically change the chemical reaction in process.

The arrows in the figure represent the flow direction of the mixed gases within the etching system. Of course, the flow directions can be reversed, as long as all flow directions within each segment of the flow path are reversed. The circulation pump continuously pumps the gases passing by so as to maintain the circulation via the two loops. The endpoint detector dynamically measures the concentration of a reaction product, such as SiF₄ gas flowing out of the etch chamber and analyzes the measured concentration to obtain the progress information on the etching process inside the etch chamber. In the embodiment of the invention, the endpoint detector is a MKS Process Sense that uses Infra-Red light to dynamically measure the concentration of SiF₄. Other detectors, such as a Residual Gas Analyzer from AMETEK may also be employed. Valves V3, V4 and V5 switch the gas flow between inner circulation loop and the outer circulation loop. Specifically, the outer circulation is activated by opening (e.g. allowing the gas to flow through) valves V3 and V4, and closing (e.g. blocking the gas to flow through) valve V5. The inner circulation loop is activated by opening valve V5 and closing valves V3 and V4.

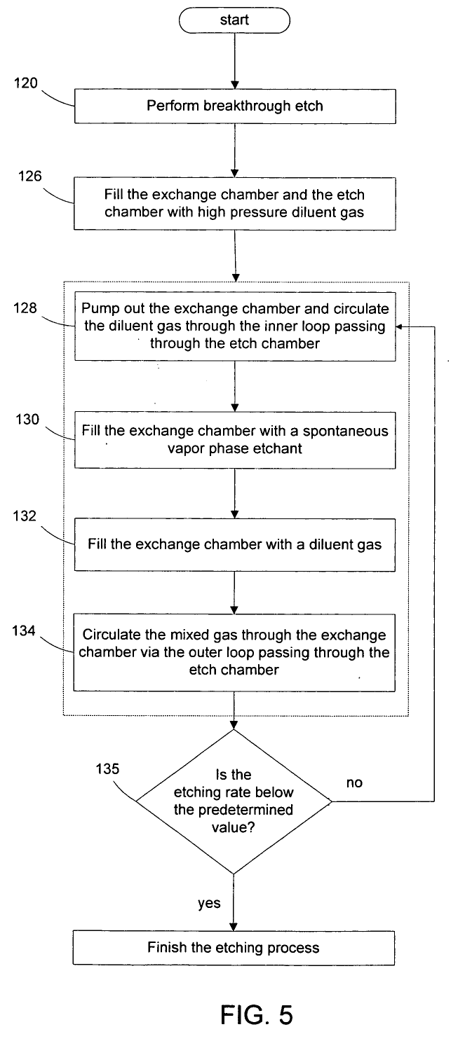

In the following, an exemplary etching process will be discussed with reference to FIG. 5, which illustrates steps executed in the exemplary etching process. For simplicity and demonstration purposes without losing the generality, the following discussion assumes that helium gas is used as the diluent gas.

Referring to FIG. 5, the etch process starts from breakthrough etch (step 120). In the breakthrough etch, XeF₂ gas is prepared in the etchant source chamber and directed to the exchange chamber through valve V₂. The prepared XeF₂ is then streamed to the plasma generator in the plasma space of the etch chamber. The plasma generator energizes XeF₂ gas into atomic radicals Xe and F. The reactive fluorine radicals are streamed to the microstructure in the process space and adsorbed to SiO₂ molecules at the sacrificial layer surface. Through a chemical reaction between molecules fluorine F and SiO₂, SiO₂ molecules are decomposed to SiF₄ and O₂, which are volatile molecules. The volatile chemical productions SiF₄ and O₂ are pumped out from the etch chamber through a vacuum pump connected to the etch chamber. When at least a portion, or preferably all oxide layers of SiO₂ is removed from the sacrificial material, the plasma generator is turned off; and the breakthrough etch is finished.

Following the breakthrough etch when the sacrificial material of amorphous silicon is exposed, the non-energized vapor phase etch process with a spontaneous vapor phase etchant is carried out, which starts from the step (step 126) of filling the exchange chamber and the etch chamber with the helium gas that has a pressure preferably from 20 to 700 torr. This filling step is achieved by opening the valves V1, V3, V4, V5; and closing the valves V2 and V6 for a time period, preferably around 500 milliseconds until the diluent gas inside the etching system reaches equilibrium. Then a sequence of etchant feeding processes is performed during a sequence of feeding cycles. Each feeding process comprises the steps of 128 through 135 in the flow chart; and is executed during each feeding cycle until the sacrificial material inside the etch chamber is either exhausted or below a predefined amount, such as less then 1% of the initial amount. For example, during the first feeding cycle, the etchant feeding process starts at pumping out the exchange chamber so as to reduce the pressure inside exchange chamber and meanwhile, circulating the diluent gas through the inner loop (step 128) for a time period preferably from 100 to 1500 milliseconds. This step is accomplished by opening valve V5 and valve V6 and closing valves V1, V2, V3 and V4. As a result, the pressure inside the exchange chamber is reduced to a pressure from 0.1 to 15 torr. The pressure inside etch chamber 106 is maintained at a pressure preferably from 20 to 700 torr. Because the pressure of the exchange chamber is equal to or below the pressure of XeF₂ inside etchant source chamber 102, XeF₂ can thus flow into the exchange chamber, which is conducted at step 130 by opening valve V2 and closing valves V1, V3, V4 and V6. At this step, valve V5 is left open—allowing the diluent gas to keep on circulating via the inner circulation loop. During this step, a first amount of XeF₂ flows into the exchange chamber. The amount can be controlled by the duration of opening valve V2. Alternatively the amount can be controlled through controlling the pressure of the exchange chamber via valve V6 and the pump connected to the exchange chamber. For example, by controlling the pumping time of the exchange chamber through controlling the open duration of valve V6, the pressure inside the exchange chamber (e.g. the total pressure of the gas mixture, which may comprises XeF₂, He, Xe and SiF₄) can be set to a pressure value, such as 1 torr, 2 torr and 3 torr, corresponding to the desired additional amount of XeF₂. For example, when the pressure inside the exchange chamber is set to 1 torr, an additional amount of XeF₂ corresponding to 3 torr (3 torr=4 torr−1 torr) is fed into the exchange chamber when valve V2 is opened. In the embodiment of the invention, the duration of opening valve V2 is preferably around 500 milliseconds. During the 500 milliseconds, around 6×10⁻⁵ mole XeF₂ gas flows into the exchange chamber from etchant source chamber 102. Then an amount, preferably around 1.6×10⁻³ mole of helium diluent gas is fed into the exchange chamber at step 132. The helium diluent gas mixes with the XeF₂ etchant gas and reaches equilibrium. Other diluent gases can also be used, which is preferably inert gases, such as N₂, Ne, Ar, Kr, and Xe. This step is accomplished by opening valve V1 and closing valves V2, V3, V4 and V6 for a time duration preferably around 100 milliseconds. After the XeF₂ gas is mixed with the helium gas, the mixed gas is then fed into etch chamber 106 at step 134. This feeding step is accomplished by opening valve V3 and valve V4 and closing the rest of the valves, including valves V1, V2, V5, and V6. It can be seen that, by closing valve V5 and opening valves V3 and V4, the inner circulation loop is closed and the outer circulation loop is opened. As a result, the mixed gas flows via the outer circulation loop and passes through the etch chamber for etching the amorphous silicon through the chemical reaction inside the etch chamber. This step may last for a time period, preferably from 1000 to 3000 milliseconds, depending upon the measurement result of the endpoint detector 109. The endpoint detector, which is preferably an MKS Process Sense dynamically measures the amount of reaction product SiF₄ flowing out the etch chamber using Infra-Red light. Other endpoint detectors, such as an RGA endpoint detector may also be used. Based on the measured value of the amount of SiF₄, an etching rate is calculated and then compared to a predetermined value (step 135). The etching rate is proportional to the derivative of the measured amount of SiF₄. If the etching rate is higher then the predetermined amount value, indicating that the sacrificial material of amorphous silicon has not been totally removed, the etching process loops back to step 128. Otherwise, the etching process is finished.

During the feeding cycle, the etchant recipe is fed into the etch chamber via the outer loop, which is switched from the inner loop (as shown in FIG. 4). When the XeF₂ is circulated through the etch chamber, a portion of the XeF₂ gas is consumed by the chemical reaction, resulting in reduction of the amount of XeF₂ in circulation. For this reason, an additional amount of XeF₂ gas is fed into the etch chamber during the second etchant feeding cycle T₂, which is initiated by the etching process looping back to step 128.

At step 128 during the second etchant feeding cycle, the exchange chamber is pumped out to reduce the pressure and exhaust the etching products and Xe gas and SiF₄ gas. Different from step 128 executed in the first etchant feeding cycle, an amount of XeF₂ recipe is still circulating through the etch chamber via the inner circulation loop. This is accomplished by opening the valves V5 and V6 and closing the rest of the valves. After step 128, a second amount of spontaneous vapor phase XeF₂ is filled into the exchange chamber (step 130) followed by filling an amount of diluent helium gas into the exchange chamber so as to mix the XeF₂ gas with the helium gas. The mixed gas is then fed into the etch chamber by stopping the inner circulation loop and opening the outer circulation loop (step 134).

Each one of these steps (steps 128 through 134) during the second feeding cycle is executed for a certain time period. For example, step 128 is executed for a time period preferably from 100 to 1500 milliseconds. The time period for executing step 130 is preferably around 500 milliseconds, and the time period for step 132 is preferably around 100 milliseconds. The etchant circulation step of 134 is preferably from 1000 to 3000 milliseconds. Of course, the time period of each step may be adjusted. For example, the time period for step 130, in which the exchange chamber is filled with XeF₂, may be reduced when less amount of XeF₂ is expected to be fed into the etch chamber. This may happen especially when less than the expected amount of XeF₂ is consumed in the etch chamber during the previous etchant feeding cycle and close to the end of the etching process when the amount of the sacrificial material inside the etch chamber is small. The time period of step 134, in which the mixed gas is circulated via the outer loop through the etch chamber is also adjustable. In particular, the time period can be increased when, for example, the XeF₂ gas consuming rate (defined as the amount of XeF₂ in molar mass consumed per millisecond) is lower than expected (e.g. the initial consuming rate). And the time period can be reduced when the XeF₂ consuming rate is higher than the expected. As a general situation according to the embodiment, the time duration of each etchant feeding cycle, thus the total time period of executing steps 128 through 135, is preferably from 7.5 to 15 seconds.

As the mixed gas of XeF₂ and helium circulate via the outer loop, the endpoint detector measures the amount of SiF₄ flowing out the etch chamber and the derivative of the measured amount over time. If a decrease (the derivative) of the measured amount is larger than the predetermined value, indicating that the sacrificial material inside the etch chamber has not been totally removed, the etching process loops back to step 128 and starts the third etchant feeding cycle. Otherwise, the etching process is terminated. Any suitable endpoint detection methods can be used, such as that set froth in U.S. patent application Ser. No. 10/269,149 filed Oct. 12, 2002, the subject matter being incorporated herein by reference in entirety.

When the amount of the sacrificial material inside the etch chamber is below the predetermined value, the etching process can be terminated and the microstructure can be unloaded from the etch chamber, or processed further, such as coating the microstructure with self-assembled-monolayer (SAM) or other passivation or anti-stiction materials. The SAM coating process can be formed in the SAM chamber as shown in FIG. 4. The SAM chamber is a place where the released microstructure can be coated with a self-assembled-monolayer (SAM) material. The SAM material is kept in the SAM container. Switching of the released microstructure sample can be performed through a load-lock that connects the etch chamber and SAM chamber such that, switching of the microstructure sample from one chamber to the other will not expose the microstructure sample to the environment.

After the removal of the sacrificial materials such as amorphous silicon, materials of the functional layers of the microstructure are left. Exemplary such materials of the functional layers comprises: metal elements (e.g. Al, Ir, Ti, Ag, W, Ta and Mo), metal alloys (e.g. WTiₓ, WMoₓ, and WTaₓ), metal compounds (e.g. WAlₓ, AlTiₓ) including metal silicides (e.g. AlSiₓ, WSiₓ, MoSiₓ, TiSiₓ, ZrSiₓ, CrSiₓ, TaSiₓ, AlSiₓCu_{y} and TiWₓSi_{y}), ceramic materials (e.g. silicon nitride, silicon carbide, polysilicon, titanium nitride, titanium oxide(s), titanium carbide, CoSiₓN_{y}, TiSiₓN_{y}, TaSiₓN_{y}, or other ternary and higher compounds).

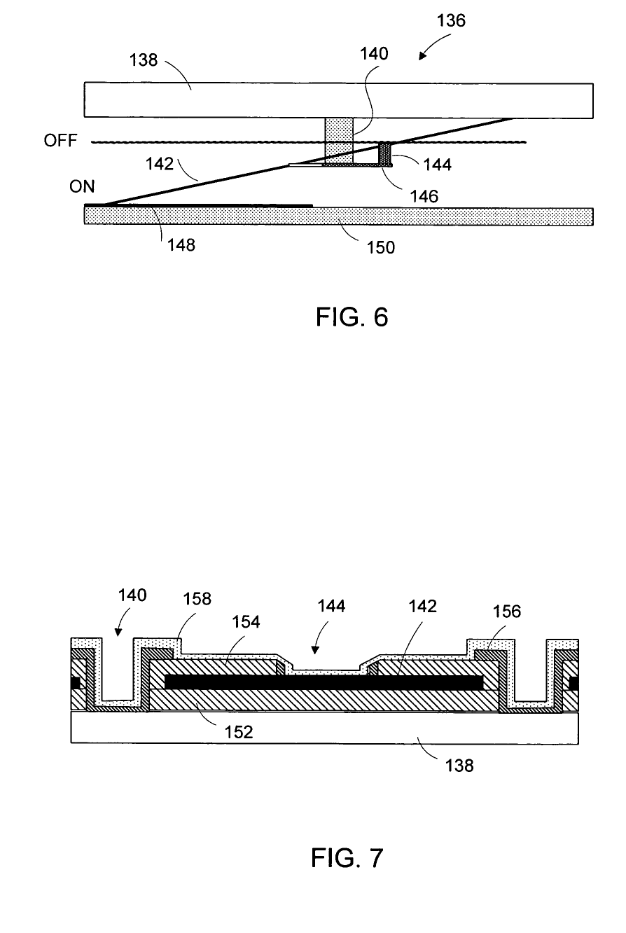

The microstructures in the etch chamber can be any suitable microstructures having a sacrificial material, such as microelectromechanical devices including but not limited to semiconductor devices, micromirror devices, integrated circuit devices, image capturing devices and other electronic devices. An exemplary micromirror device is schematically illustrated in a cross-sectional view in FIG. 6.

Referring to FIG. 6, the micromirror device comprises reflective deflectable mirror plate 142 attached to deformable hinge 146 via hinge contact 144. The deformable hinge is connected to and held by post 140 formed on light transmissive substrate 138, such as glass, sapphire, and quartz. With this configuration, the mirror plate is capable of moving relative to the substrate (e.g. substrate 138) on which the mirror plate is formed. Movement (deflection) of the mirror plate is accomplished through an addressing electrode (e.g. addressing electrode 148) that is placed proximate to and associated with the mirror plate. The addressing electrode can be formed on substrate 150 that is a semiconductor substrate on which standard integrated circuits and semiconductor devices can be fabricated. The semiconductor substrate is bonded to the light transmissive substrate. In operation, electrical voltages are applied to the mirror plate and the associated addressing electrode so as to generate an electrostatic field between the mirror plate and addressing electrode. Such electrostatic field yields an electrostatic force with a strength sufficient for deflecting the mirror plate relative to the substrate (e.g. substrate 138). By adjusting the magnitude of the voltage applied to the addressing electrode, different rotation angles of the mirror plate can be achieved.

The micromirror as shown in FIG. 6 may have other alternative features. For example, a light transmissive electrode for deflecting the mirror plate towards substrate 138 can be formed on the lower surface of substrate 138. For preventing unintentional electrical short between the mirror plate and the light transmissive electrode if provided, a light transmissive and electrically conductive layer may be coated on the light transmissive electrode. Alternative to the light transmissive electrode, optical films for improving the optical properties, such as an anti-reflection film for enhancing the transmission of the incident light (e.g. visible light); and light blocking/absorbing materials (e.g. in the form of strip, frame, segments, or combinations thereof) can be coated on the light transmissive substrate 138.

The mirror plate can be attached to the deformable hinge via hinge contact wherein the contact point is away from the mass center of the mirror plate such that the rotation axis along which the mirror plate rotates is not coincident with any diagonals of the mirror plate (but may or may not be parallel to a diagonal of the mirror plate); and the mirror plate is thus capable of rotating asymmetrically. That is, the maximum achievable angle (e.g. the ON state angle) of the mirror plate rotating in one direction is larger than that (e.g. the OFF state angle) of the mirror plate in rotating along the opposite direction. Alternatively, the mirror plate can be attached to the deformable hinge such that the mirror plate is capable of rotating symmetrically—that is the maximum achievable angles in both directions are substantially the same. This can be accomplished by attaching the mirror plate to the deformable hinge at an attachment point that is substantially at the mass center of the mirror plate, which is not shown in the figure.

Regardless of whether the attachment point is at or away from the mass center of the mirror plate, the mirror plate and deformable hinge can be formed on different planes when the mirror plate is not deflected (after removing multiple sacrificial layers in the etch process). That is, the mirror plate and deformable hinge form a gap along the normal direction of the mirror plate when the mirror plate is not deflected, as that shown in the figure. Alternatively, the mirror plate and deformable hinge can be formed on the same plane. In particular, the mirror plate and deformable hinge can be derived from a same material. For example, the mirror plate and hinge can be derived from a single crystal, such as single crystal silicon.

In the examples shown in FIG. 6, the mirror plates and addressing electrodes are formed on separate substrates (e.g. semiconductor substrate 150 and light transmissive substrate 138), alternatively, the mirror plate and addressing electrode can be formed on the same substrate, such as the semiconductor substrate (e.g. substrate 150).

The micromirror devices as discussed above can be fabricated in many ways. An exemplary fabrication method for making a micromirror in FIG. 6 is demonstratively illustrated in FIG. 7. Referring to FIG. 7, first sacrificial material 152, such as amorphous silicon is deposited on substrate 138 that is transmissive to visible light. A mirror plate layer, or multiple mirror plate layers (e.g. a metallic reflective layer, a mechanical enhancing layer, and other functional layers, such as a barrier layer) are deposited on the first sacrificial layer and patterned into mirror plate 142 with the desired shape. Second sacrificial layer 154 is then deposited on the patterned mirror plate and first sacrificial layer following by patterning so as to form posts 140 and hinge contact 144. Hinge support layer(s) 156 can be deposited and patterned so as to form a hinge support (if needed) and posts 140. The side walls of hinge contact 144 are also filled with the hinge support material(s) to improving the mechanical properties of the hinge contact. Exemplary hinge support layers are TiNₓ, SiNₓ, or a combination thereof.

Hinge layer 158, such as a layer comprising TiNₓ, is then deposited and patterned so as to form the deformable hinge. It is preferred that the hinge comprises an electrically conductive material, and such electrically conductive material is electrically connected to the electrically conductive layer of the mirror plate at the hinge contact (e.g. as that shown in the figure) such that electrical voltage signals can be applied to the mirror plate through the deformable hinge and hinge contact.

After forming the functional members of the micromirror, the first and second sacrificial layers are removed by etching using the releasing method as discussed above with reference to FIGS. 1 to 5, and will not be repeated herein. The released micromirror after removal of the sacrificial layers is then assembled to the addressing electrode so as to form a micromirror device.

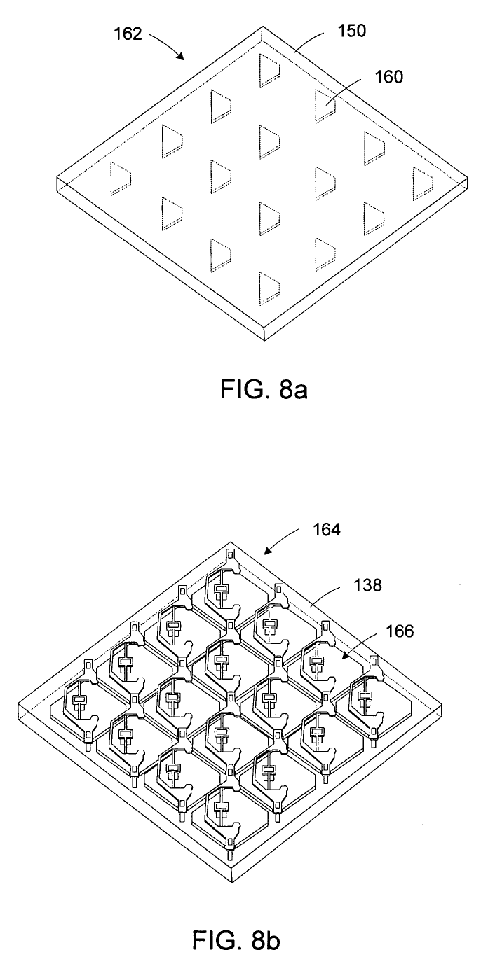

The above fabrication method is discussed with reference to making one single micromirror device. However, a micromirror array device having an array of micromirror devices can be fabricated in the same method. Referring to FIGS. 8a and 8b, FIG. 8a demonstratively illustrates an array of addressing electrodes (e.g. addressing electrode 160) on semiconductor substrate 150. For simplicity purposes, only 4×4 addressing electrodes are shown in the figure. In general, the micromirror array of a spatial light modulator may consist of thousands or millions of micromirrors, the total number of which determines the resolution of the displayed images. For example, the micromirror array of the spatial light modulator may have 1024×768 or more, 1280×720 or more, 1400×1050 or more, 1600×1200 or more, 1920×1080 or more, or even larger number of micromirrors. In other applications, the micromirror array may have less number of micromirrors.

FIG. 8b schematically illustrates an array of micromirrors (e.g. micromirror 166) each having a reflective mirror plate formed on light transmissive substrate 138. The micromirrors can be fabricated with the fabrication method discussed with reference to FIG. 7. After releasing the sacrificial materials, the released micromirrors are assembled to the array of addressing electrodes on the semiconductor substrate such that each mirror plate of the micromirrors is associated with an addressing electrode of the array of addressing electrodes. The assembled micromirrors and addressing electrodes are often referred to as a micromirror array device.

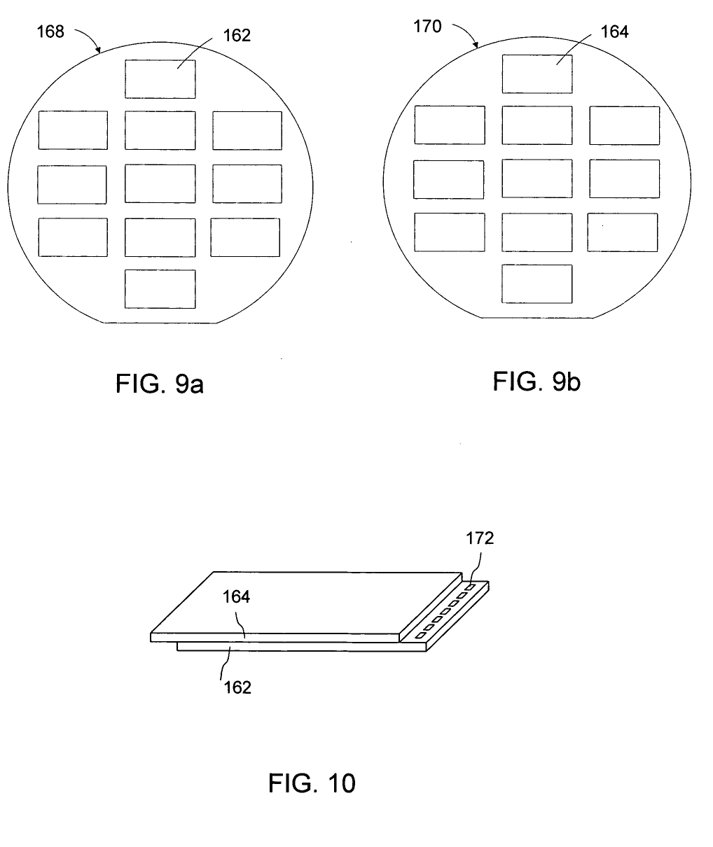

The micromirror array devices can be fabricated at the wafer level, as shown in FIGS. 9a and 9B. Referring to FIG. 9a, a plurality of electrode dies (e.g. electrode die 162) each having an array of addressing electrodes (e.g. addressing electrode array 162 in FIG. 8a) is fabricated on semiconductor wafer 168. A plurality of mirror dies (e.g. mirror die 164) each having an array of micromirrors (e.g. micromirror array 164 in FIG. 8b) is fabricated and released on light transmissive wafer 170. The electrode dies and micromirror dies are assembled together by assembling each micromirror die with an electrode die. The assembled micromirror and electrode dies are then singulated. A singulated die assembly is demonstratively illustrated in FIG. 10.

Referring to FIG. 10, light transmissive substrate 164 having formed thereon an array of reflective deflectable mirror plates is bonded to a semiconductor substrate 162 having an array of addressing electrodes. The two substrates can be offset in one direction such that a portion of the semiconductor substrate can be exposed forming a ledge, on which a plurality of electrical contacts 172 can be formed. The electrical contacts can be used to deliver external signals to the mirror plates and addressing electrodes enclosed within the gap between the two substrates.

It will be appreciated by those skilled in the art that a new and useful releasing method and apparatus have been described herein. In view of the many possible embodiments to which the principles of this invention may be applied, however, it should be recognized that the embodiments described herein with respect to the drawing figures are meant to be illustrative only and should not be taken as limiting the scope of invention. For example, those of skill in the art will recognize that the illustrated embodiments can be modified in arrangement and detail without departing from the spirit of the invention.

1. A method comprising:
loading a sample into an etch chamber, said sample comprising a sacrificial layer comprising a sacrificial material;
removing a portion of the sacrificial layer using a downstream plasma etch process with a gaseous etching agent, wherein the etching agent comprises an etchant that is interhalogen or noble gas halide; and
removing the sacrificial layer using a non-energized etching with an etching agent that comprises said etchant, said etchant being capable of spontaneously and chemically reacting with the sacrificial material of the sacrificial layer.

2. The method of claim 1, wherein no energized plasma radicals are generated during the non-energized etching

3. The method of claim 1, wherein the step of removing a portion of the sacrificial layer using a downstream plasma etch process further comprises:
generating a stream of plasma radicals from the etchant; and
streaming the generated plasma radicals to the sample.

4. The method of claim 3, wherein the sample is a microstructure.

5. The method of claim 3, wherein the microstructure is a microelectromechanical device.

6. The method of claim 5, wherein the microelectromechanical device is a micromirror device having a reflective and deflectable mirror plate attached to a deformable hinge.

7. The method of claim 6, wherein the mirror plate is formed on a light transmissive substrate.

8. The method of claim 6, wherein the mirror plate is formed on a semiconductor substrate having formed thereon an addressing electrode.

9. The method of claim 6, wherein the mirror plate is derived from a single crystal.

10. The method of claim 1, wherein the sacrificial material comprises amorphous silicon; and the etchant comprises XeF₂.

11. The method of claim 10, wherein the sacrificial layer comprises a surface layer of SiO₂.

12. The method of claim 11, wherein the plasma etching and non-energized etching are performed in the same etch chamber.

13. The method of claim 2, further comprising:
turning off the plasma generator before performing the step of removing the sacrificial layer using a non-energized etching with said gaseous etchant.

14. The method of claim 10, wherein the XeF₂ gas passes through the plasma generator that is turned off to a process space.

15. The method of claim 12, wherein the process space and plasma space is connected to each other.

16. The method of claim 14, wherein the XeF₂ gas is streamed continuously throughout the entire step of removing the sacrificial layer using a plasma etching with a gaseous etchant.

17. The method of claim 14, wherein the XeF₂ gas is streamed intermittently over time during the step of removing the sacrificial layer using a plasma etching with a gaseous etchant.

18. The method of claim 14, wherein the XeF₂ gas is streamed into the plasma generator through a circulation loop that passes through the process space of the etch chamber during the step of removing the sacrificial layer using a plasma etching with a gaseous etchant.

19. The method of claim 14, wherein the XeF₂ gas is streamed into the plasma generator without a circulation loop that passes through the process space of the etch chamber during the step of removing the sacrificial layer using a plasma etching with a gaseous etchant.

20. The method of claim 1, wherein the step of removing the sacrificial layer using a non-energize etching with said gaseous etchant further comprises:
mixing the XeF₂ gas with a diluent gas.

21. The method of claim 20, wherein the diluent gas comprises an inert gas.

22. The method of claim 21, wherein the diluent gas is helium.

23. The method of claim 21, wherein the diluent gas is nitrogen.

24. The method of claim 1, wherein the step of removing the sacrificial layer using a non-energize etching with said gaseous etchant further comprises:
streaming the etchant into the etch chamber through a first circulation loop that passes through a process space of the etch chamber.

25. The method of claim 1, further comprising:
stopping the step of streaming the into the etch chamber through a first circulation loop; and
circulating the etchant in a second circulation loop that passes through the process space of the etch chamber.

26. The method of claim 1, wherein the step of removing the sacrificial layer using a non-energize etching with said gaseous etchant further comprises:
streaming the etchant into the etch chamber without a circulation loop that passes through a process space of the etch chamber.

27. The method of claim 26, wherein the etchant is delivered to the etch chamber intermittently over the step of removing the sacrificial layer using a non-energize etching with said gaseous etchant.

28. The method of claim 26, wherein the etchant is delivered to the etch chamber continuously throughout the step of removing the sacrificial layer using a non-energize etching with said gaseous etchant.

29. A method, comprising:
loading a sample into an etch chamber, said sample comprising a sacrificial layer comprising a sacrificial material; and
removing at least a portion of the sacrificial layer using a downstream plasma etch process with an etching agent that comprises XeF₂.

30. The method of claim 29, wherein the step of removing at least a portion of the sacrificial layer using a downstream plasma etch process further comprises:
generating a stream of plasma radicals from the etching agent; and
streaming the generated plasma radicals to the sample.

31. The method of claim 30, further comprising:
removing the sacrificial layer using a non-energized etching with an etching agent that comprises said etching agent.

32. The method of claim 30 wherein the sample is a microstructure.

33. The method of claim 32, wherein the microstructure is a MEMS device.

34. The method of claim 33, wherein the MEMS device is a micromirror device having a reflective and deflectable mirror plate attached to a deformable hinge.

35. The method of claim 34, wherein the mirror plate is formed on a light transmissive substrate.

36. The method of claim 34, wherein the mirror plate is formed on a semiconductor substrate having formed thereon an addressing electrode.

37. The method of claim 34, wherein the mirror plate is derived from a single crystal.

38. The method of claim 30, wherein the sacrificial material comprises amorphous silicon.

39. The method of claim 30, wherein the sacrificial layer comprises a surface layer of SiO₂.

40. The method of claim 31, wherein the plasma etching and non-energized etching are performed in the same etch chamber.

41. The method of claim 40, further comprising:
turning off the plasma generator before performing the step of removing the sacrificial layer using a non-energized etching with said gaseous etchant.

42. The method of claim 41, wherein the XeF₂ gas passes through the plasma generator that is turned off to a process space.

43. The method of claim 40, wherein the XeF₂ gas is streamed continuously throughout the entire step of removing the sacrificial layer using a plasma etching with a gaseous etchant.

44. The method of claim 40, wherein the XeF₂ gas is streamed intermittently over time during the step of removing the sacrificial layer using a plasma etching with a gaseous etchant.

45. The method of claim 40, wherein the XeF₂ gas is streamed into the plasma generator through a circulation loop that passes through the process space of the etch chamber during the step of removing the sacrificial layer using a plasma etching with a gaseous etchant.

46. The method of claim 40, wherein the XeF₂ gas is streamed into the plasma generator without a circulation loop that passes through the process space of the etch chamber during the step of removing the sacrificial layer using a plasma etching with a gaseous etchant.

47. The method of claim 30, wherein the step of removing the sacrificial layer using a non-energize etching with said gaseous etchant further comprises:
streaming the etchant into the etch chamber through a first circulation loop that passes through a process space of the etch chamber.

48. The method of claim 47, further comprising:
stopping the step of streaming the into the etch chamber through a first circulation loop; and
circulating the etchant in a second circulation loop that passes through the process space of the etch chamber.

49-62. (canceled)

63. A method, comprising:
loading a sample into an etch chamber, said sample comprising a sacrificial layer comprising a sacrificial material;
removing a portion of the sacrificial layer using a plasma etch process with a gaseous etching agent, wherein the etching agent comprises an etchant that is interhalogen or noble gas halide, said etchant being capable of spontaneously and chemically reacting with the sacrificial material of the sacrificial layer;
removing the sacrificial layer using a non-energized etching with an etching agent that comprises said etchant; and
wherein the etchant is introduced into the etch chamber through a circulation loop that passes through the etch chamber.

64. The method of claim 63, wherein the step of removing a portion of the sacrificial layer using a downstream plasma etch process further comprises:
generating a stream of plasma radicals from the etchant; and
streaming the generated plasma radicals to the sample.

65. The method of claim 64, wherein the sample is a microstructure.

66-82. (canceled)
